(19) United States
(12) Patent Application Publication
(10) Pub. No.: US 2007/0120213 A1
(43) Pub. Date: May 31, 2007

(54) Wire under dam package and method for packaging image-sensor

(76) Inventors: Siew Sin Hiew, San Jose, CA (US); Chih Hung Hsieh, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/287,273

(22) Filed: Nov. 28, 2005

(51) Int. Cl. H01L 21/00; H01L 31/0203

(52) U.S. Cl. 257/433; 438/64; 257/434; 257/698

(57) ABSTRACT

An wire under dam package and method for packaging image-sensor. The image-sensor package includes: a substrate having a first surface and a second surface, a sensing chip being laid on the first surface, the sensing chip having multiple soldering pads; multiple inner electric contacts arranged on the first surface, the soldering pads and the inner electric contacts being electrically connected via soldering wires; a frame bank attached to the first surface, rear ends of the soldering wires soldered with the inner electric contacts being sandwiched between the frame bank and the first surface; and a transparent board laid on the frame bank for sealing the sensing chip.

### BACKGROUND OF THE INVENTION

The present invention is related to an image-sensor package and a method for packaging image-sensor. The frame bank is attached to the substrate with the rear ends of the soldering wires sandwiched between the frame bank and the substrate. Accordingly, the width and size of the package are minified.

A conventional image-sensor includes an image-sensing chip and a base seat in which the image-sensing chip is installed. The base seat is molded with a lead frame or formed of a printed circuit board, ceramic/porcelain substrate and frame bank sealed and covered by a transparent glass board.

Currently, the image-sensors are widely applied to various electronic products such as digital cameras, cellular phones and PDA. These electronic products require cheap and small-size image-sensors. By means of the new generation of flip chip package, CSP image-sensors are producible. However, such CSP image-sensors are relatively expensive. FIG. 6 shows one of the popular packages of the image-sensors. The package includes a substrate 60, a frame bank 61, a chip 62 and a transparent glass board 63. Multiple circuits 601 are laid on the surface of the substrate. The circuits extend to outer side of the chip to electrically connect with the soldering wires 621 and soldering pads of the chip. The transparent glass board 63 is adhered to the frame bank for sealing the chip. In such package, a sufficient gap must be reserved between the chip 62 and the frame bank 61 for the circuits 601 on the surface of the substrate. Therefore, such package has a considerable width.

FIG. 7 shows an improved image-sensor package including a substrate 70, a frame bank 71, a chip 72 and a transparent glass board 73. The main difference between the two packages is that one end of the soldering wire 721 is soldered on upper side of the frame bank 71. Therefore, the size of the frame bank is only slightly larger than that of the chip and thus the volume of the package is greatly reduced. However, such design is still not optimal. For example, the soldering pad 701 is laid on the upper side of the frame bank 71. A lead 702 extends from the soldering pad 701 along outer side of the frame bank to the bottom face of the substrate. It is hard to manufacture the lead 702.

### SUMMARY OF THE INVENTION

It is therefore a primary object of the present invention to provide wire under dam package and method for packaging image-sensor. Multiple inner electric contacts are arranged on a first surface of the substrate. The soldering pads of the sensing chip and the inner electric contacts are electrically connected via soldering wires. A frame bank is attached to the first surface. Rear ends of the soldering wires soldered with the inner electric contacts are sandwiched between the frame bank and the first surface. Accordingly, the area of the substrate is reduced to minify the size of the package.

According to the above object, the method for packaging image-sensor of the present invention includes steps of:

preparing a substrate having a first surface and a second surface;

arranging multiple inner electric contacts on the first surface;

laying a sensing chip on the first surface of the substrate, the sensing chip having multiple soldering pads;

electrically connecting the soldering pads with the inner electric contacts with soldering wires;

adhering a frame bank to the periphery of the first surface, whereby rear ends of the soldering wires soldered with the inner electric contacts are sandwiched between the frame bank and the first surface; and

laying a transparent board on the frame bank.

The present invention can be best understood through the following description and accompanying drawings wherein:

### BRIEF DESCRIPTION OF THE DRAWINGS

FIG. 1 is a sectional view of a first embodiment of the image sensor package of the present invention;

FIG. 2 is a sectional view of a second embodiment of the image sensor package of the present invention;

FIG. 3 is a sectional view showing that the soldering wire is pressed down by the frame bank of the present invention;

FIG. 4 is a perspective exploded view of the image sensor package of the present invention, showing that the bottom face of the frame bank is formed with multiple recesses in which the rear ends of the soldering wires are accommodated;

FIG. 5 is a flow chart of the packaging method of the present invention;

FIG. 6 is a sectional view of a conventional image sensor package; and

FIG. 7 is a sectional view of another conventional image sensor package.

### DETAILED DESCRIPTION OF THE PREFERRED EMBODIMENTS

Please refer to FIG. 1 which shows the image-sensor package of a first embodiment of the present invention. The package includes a substrate 10 having a first surface 11 and a second surface 12. A sensing chip 2 is laid on the first surface. The sensing chip has multiple soldering pads 21.

Multiple inner electric contacts 13 are arranged on the first surface 11. The soldering pads 21 and the inner electric contacts 13 are electrically connected via soldering wires 22.

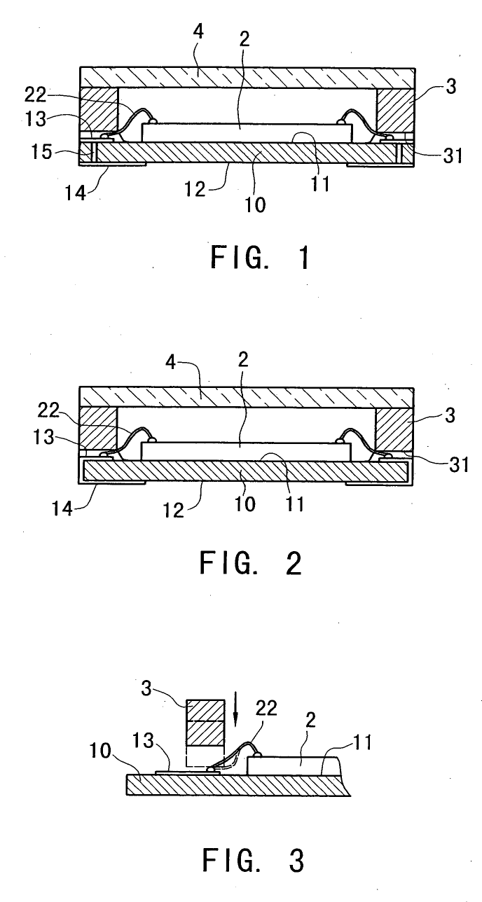

Multiple outer electric contacts 14 are arranged on the second surface 12 of the substrate for connecting with an external circuit of another circuit board. As shown in FIG. 1, multiple guide holes 15 are formed through the substrate between the inner electric contacts 13 and the outer electric contacts 14. Conductive material is filled in the guide holes 15 to electrically connect the inner electric contacts 13 with the outer electric contacts 14. Alternatively, as shown in FIG. 2, the inner electric contacts 13 extend along the lateral side of the substrate to electrically connect with the outer electric contacts 14.

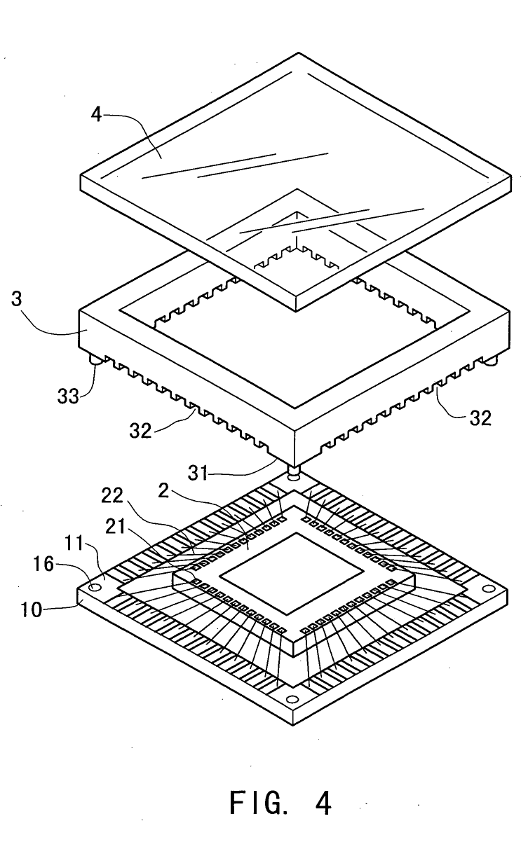

A frame bank 3 is adhered to the first surface with adhesive glue. A transparent board 4 is adhered to upper side of the frame bank 3. The frame bank 3 has a bottom face 31 facing the first surface. A rear end of the soldering wire soldered with the inner electric contact is sandwiched between the bottom face 31 of the frame bank and the first surface 11. In order to avoid thickening of the package, as shown in FIG. 4, the bottom face 31 of the frame bank is formed with multiple recesses 32 in each of which the rear end of a corresponding soldering wire is accommodated.

In addition, several bosses 33 are disposed under the bottom face of the frame bank and the substrate is formed with several sockets 16 corresponding to the bosses 33. Accordingly, the bosses 33 can be inserted in the sockets 16 to more accurately associate the frame bank with the substrate.

The soldering wires have good extensibility and flexibility. Therefore, when the frame bank is attached to the substrate, the rear ends of the soldering wires near the inner electric contacts can be pressed down as shown in FIG. 3. Therefore, the frame bank can surround the chip in a position closer to the periphery of the chip. Accordingly, the package can have a size nearly equal to the size of the chip.

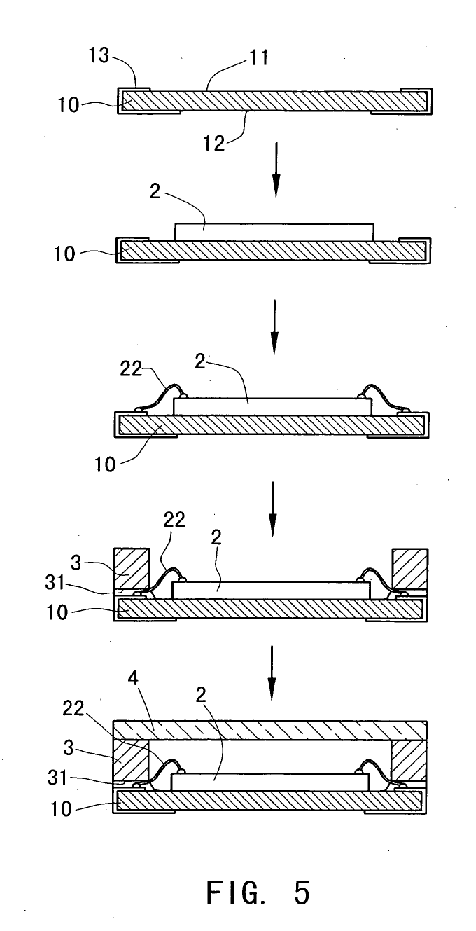

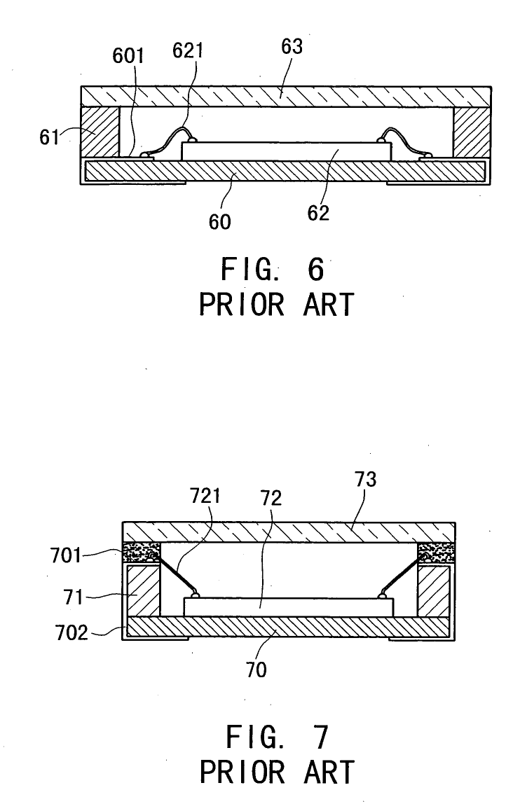

FIG. 5 shows the packaging method of the present invention, including steps of:
a) preparing a substrate 10 having a first surface 11 and a second surface 12, multiple inner electric contacts 13 being arranged on the first surface 11;
b) laying a sensing chip 2 on the first surface of the substrate, the sensing chip having multiple soldering pads;
(c) electrically connecting the soldering pads with the inner electric contacts with soldering wires 22;
(d) painting adhesive glue on a periphery of the first surface 11 of the substrate and adhering a frame bank 3 to the first surface, whereby rear ends of the soldering wires soldered with the inner electric contacts are sandwiched between the frame bank and the first surface; and
(e) laying a transparent board 4 on the frame bank.

The image sensor achieved by the above packaging method has a reduced volume. In addition, the image sensors can be mass-produced in such a manner that a substrate connecting board having multiple substrates is provided. The substrates are interconnected with each other. After all the chips are laid on the substrate connecting board and lined, a frame bank connecting board having multiple frame banks is attached to the substrate connecting board. A transparent board with an area equal to that of the frame bank connecting board is attached to the frame bank connecting board. Finally, the substrate connecting board is cut along the sides of the substrates into independent image sensor packages.

The above embodiments are only used to illustrate the present invention, not intended to limit the scope thereof. Many modifications of the above embodiments can be made without departing from the spirit of the present invention.

What is claimed is:

1. An wire under dam package comprising:
a substrate having a first surface and a second surface, a sensing chip being laid on the first surface, the sensing chip having multiple soldering pads;
multiple inner electric contacts arranged on the first surface, the soldering pads and the inner electric contacts being electrically connected via soldering wires;
a frame bank attached to the first surface, rear ends of the soldering wires soldered with the inner electric contacts being sandwiched between the frame bank and the first surface;
and
a transparent board laid on the frame bank.

2. The wire under dam package as claimed in claim 1, wherein multiple outer electric contacts are arranged on the second surface of the substrate for connecting with an external circuit, the outer electric contacts being respectively electrically connected with the inner electric contacts.

3. The wire under dam package as claimed in claim 1, wherein the frame bank is adhered to the first surface with adhesive glue.

4. The wire under dam package as claimed in claim 3, wherein several bosses are disposed under a bottom face of the frame bank and the substrate is formed with several sockets corresponding to the bosses, whereby the bosses can be inserted in the sockets to associate the frame bank with the substrate.

5. The wire under dam package as claimed in claim 4, wherein the frame bank has a bottom face facing the first surface, the bottom face of the frame bank being formed with multiple recesses in each of which the rear end of a corresponding soldering wire is accommodated.

6. A method for packaging image-sensor, comprising steps of:
preparing a substrate having a first surface and a second surface;
arranging multiple inner electric contacts on the first surface;
laying a sensing chip on the first surface of the substrate, the sensing chip having multiple soldering pads;
electrically connecting the soldering pads with the inner electric contacts with soldering wires;
painting adhesive glue on a periphery of the first surface of the substrate;
adhering a frame bank to the periphery of the first surface, whereby rear ends of the soldering wires soldered with the inner electric contacts are sandwiched between the frame bank and the first surface; and
laying a transparent board on the frame bank.

7. The method for packaging image-sensor as claimed in claim 6, wherein multiple outer electric contacts are arranged on the second surface of the substrate, the outer electric contacts being respectively electrically connected with the inner electric contacts.

8. The method for packaging image-sensor as claimed in claim 6, wherein several bosses are disposed under a bottom face of the frame bank and the substrate is formed with several sockets corresponding to the bosses, whereby the bosses can be inserted in the sockets to associate the frame bank with the substrate.

9. The method for packaging image-sensor as claimed in claim 8, wherein the frame bank has a bottom face facing the first surface, the bottom face of the frame bank being formed with multiple recesses in each of which the rear end of a corresponding soldering wire is accommodated.
